(19) United States
(12) Patent Application Publication
(10) Pub. No.: US 2019/0158144 A1
(43) Pub. Date: May 23, 2019

(54) RINGING SUPPRESSION CIRCUIT

(71) Applicant: DENSO CORPORATION, Kariya-city (JP)

(72) Inventors: Takuya HONDA, Kariya-city (JP); Hirofumi ISOMURA, Kariya-city (JP); Tomohisa KISHIGAMI, Kariya-city (JP)

(21) Appl. No.: 16/252,805

(22) Filed: Jan. 21, 2019

Related U.S. Application Data
(63) Continuation of application No. PCT/JP2017/018189, filed on May 15, 2017.

(30) Foreign Application Priority Data
Jul. 29, 2016 (JP) 2016-149795

(51) Int. Cl. H04B 3/42; H03K 5/1252

(52) U.S. Cl. CPC H04B 3/42; H03K 17/687; H03K 5/1252

(57) ABSTRACT

A ringing suppression circuit is provided at a node having a communication circuit executing communication with another node by transmitting a differential signal through a pair of communication lines. The ringing suppression circuit includes a suppressor configured to perform a suppression operation to suppress ringing occurred with a transmission of the differential signal by connecting an adjustment circuit between the pair of communication lines. The adjustment circuit includes a resistive component and a capacitive component connected in series.

### CROSS REFERENCE TO RELATED APPLICATIONS

The present application is a continuation application of International Patent Application No. PCT/JP2017/018189 filed on May 15, 2017, which designated the U.S. and claims the benefit of priority from Japanese Patent Application No. 2016-149795 filed on Jul. 29, 2016. The entire disclosures of all of the above applications are incorporated herein by reference.

### TECHNICAL FIELD

The present disclosure relates to a ringing suppression circuit,

### BACKGROUND

When transmitting a digital signal via a transmission line configured by a pair of communication lines, a part of a signal energy may be reflected when a signal level changes at a receiving end, and waveform distortion such as overshoot or undershoot, that is, ringing may occur in the signal. A variety of techniques have been proposed for suppressing the waveform distortion.

### SUMMARY

The present disclosure relates to a ringing suppression circuit for suppressing ringing caused by the transmission of a differential signal through a pair of communication lines.

### BRIEF DESCRIPTION OF DRAWINGS

The above and other objects, features and advantages of the present disclosure will become more apparent from the following detailed description made with reference to the accompanying drawings, in which:

FIG. 1 is a drawing that schematically shows the brief configuration of a ringing suppression circuit according to a first embodiment;

FIG. 2 is a drawing that schematically shows the configuration of communication network;

FIG. 3 is a drawing that schematically shows an example of the configuration of a ringing suppression circuit;

FIG. 4 is a drawing that illustrates the simulation results respectively related to the operation of a ringing suppression circuit according to a comparative example and the operation of the ringing suppression circuit according to the first embodiment;

FIG. 5 is a drawing that schematically shows the configuration (the first example) of a ringing suppression circuit according to a second embodiment;

FIG. 6 is a drawing that schematically shows the configuration (the second example) of the ringing suppression circuit according to the second embodiment;

FIG. 7 is a drawing that shows the simulation result related to the operation of the ringing suppression circuit according to the second embodiment;

FIG. 8 is a drawing that schematically shows the configuration (the first example) of a ringing suppression circuit according to a third embodiment;

FIG. 9 is a drawing that schematically shows the configuration (the second example) of the ringing suppression circuit according to the third embodiment; and

FIG. 10 is a drawing that schematically shows the configuration (the third example) of the ringing suppression circuit according to the third embodiment.

### DETAILED DESCRIPTION

For example, a ringing suppression circuit may be configured with a simpler structure to suppress the ringing for enhancing the communication fidelity. For this ringing suppression circuit, a switching device is provided in a communication bus and is configured to be turned on with a predetermined time period when a change in a signal's level is detected. With regard to the ringing suppression circuit as described above, when noise is superimposed on the communication line, the suppression operation for ringing suppression may be erroneously performed. When the suppression operation is performed, the DC impedance between the communication lines changes instantaneously, for example, from 100 kΩ to 120 Ω. When a variation in the DC current flowing through the communication lines gets larger, it requires a relatively longer time until the signal level of a communication bus returns to a situation before having the influence of noise. Accordingly, a fault such as the reception of erroneous data may occur.

According to an aspect of the present disclosure, a ringing suppression circuit is provided at a node having a communication circuit executing communication with another node by transmitting a differential signal through a pair of communication lines. The ringing suppression circuit includes a suppressor configured to perform a suppression operation to suppress ringing occurred with a transmission of the differential signal by connecting an adjustment circuit between the pair of communication lines, the adjustment circuit including a resistive component and capacitive component connected in series.

According to such a configuration, when the suppression operation is performed, the resistive component and the capacitive component are connected in series between a pair of the communication lines, and thus the DC impedance between the communication lines does not vary significantly. Even when the suppression operation is erroneously performed due to noise superimposing on the communication lines, the DC current flowing through the communication lines does not vary significantly. Therefore, the signal level of the differential signal returns to the situation before having the influence of noise within a relatively shorter time. According to the configuration as described above, even when the suppressor has an erroneous operation caused by the influence of noise, it is possible to attain the effect in preventing the occurrence of a fault.

Hereinafter, multiple embodiments will be described with reference to the drawings. Hereinafter, in the respective embodiments, substantially the same configurations are denoted by identical symbols, and repetitive description will be omitted.

### FIRST EMBODIMENT

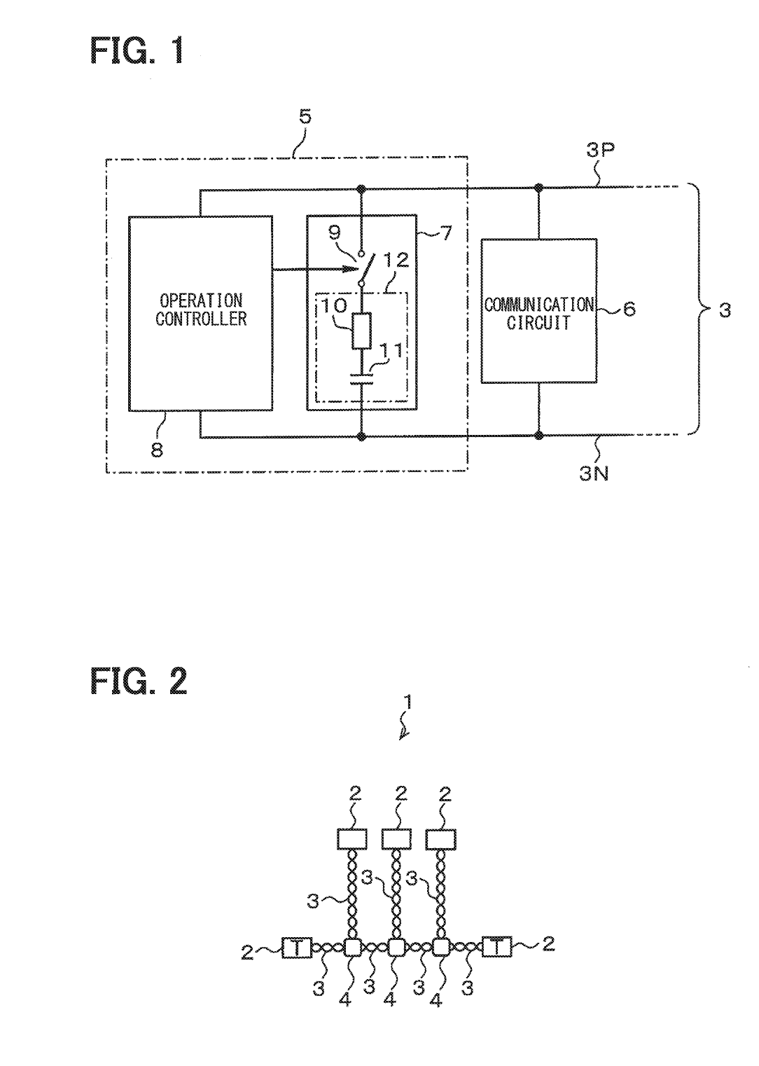

Hereinafter, a first embodiment will be described with reference to FIG. 1 to FIG. 4.

A communication network 1 illustrated in FIG. 2 refers to a network where a plurality of nodes 2 is connected through a transmission line 3, which is configured by a twisted-pair line, for controlling communication among the plurality of nodes 2 to be mounted to a vehicle. Each of the nodes 2 is an electronic control unit configured to control an actuator based on information sent from a sensor-like device or a sensor used to detect a vehicle state.

Each node 2 is provided with a communication circuit (not shown), and transmission data or receiving data is converted to a communication signal according to a communication protocol, for example, CAN protocol, at the transmission line 3. Each node 2 performs communication, in other words, transmitting or receiving data, with the other node 2. A branch connector 4 is provided at the midway of the transmission line 3, in other words, the communication bus. The branch connector 4 is configured to divide the transmission line 3 into several paths appropriately.

Among the nodes 2 illustrated in FIG. 2, the node 2 denoted as “T” in a rectangle refers to a node having a terminating resistance outside the node 2. Among the nodes 2 illustrated in FIG. 2, the node 2 without an indication in a rectangle refers to a node having no terminating resistance. In this case, the value of the terminating resistance is, for example, 120 Ω.

A ringing suppression circuit 5 illustrated in FIG. 1 and a communication circuit 6 configured to transmit and receive data are provided at the node 2 illustrated in FIG. 2. The ringing suppression circuit 5 includes a suppressor 7 and an operation controller 8. The suppressor 7 lowers the impedance of the transmission line 3 including a high-potential signal line 3P and a low-potential signal line 3N to perform a suppression operation for suppressing ringing caused by the transmission of a differential signal. The high-potential signal line 3P and the low-potential signal line 3N correspond to a pair of transmission lines (hereinafter referred to as a signal line 3P and a signal line 3N for simplicity in some occasions).

The suppressor 7 includes a switch 9, a resistive component 10 and a capacitive component 11. The switch 9, the resistive component 10 and the capacitive component 11 are connected in series in order between the signal lines 3P and 3N. An adjustment circuit 12 is configured by a series circuit having the resistive component 10 and the capacitive component 11.

Since the switch 9 is to be controlled by the operation controller 8, the switch 9 is turned on when the suppression operation is performed, and is turned off when the suppression operation is not performed. As the switch 9 is turned on, the adjustment circuit 12 having the resistive component 10 and the capacitive component 11 connected in series is connected between the signal lines 3P and 3N, and the transmission line 3 is to be AC-terminated. As a result, the AC impedance (hereinafter referred to as “line impedance”) between the signal lines 3P and 3N is lowered. In this case, the line impedance is, for example, around 100 kΩ when the switch 9 is turned off. However, the line impedance is, for example, around 120 Ω when the switch 9 is turned on. It is noted that the resistance value of the resistive component 10 and the capacitance value of the capacitive component 11 are set according to, for example, the characteristic impedance of the transmission line 3 or the length of the transmission line 3. In particular, the resistance value of the resistive component 10 and the capacitance value of the capacitive component 11 are set so that the line impedance at a time of the switch 9 being at on-state conforms to the characteristic impedance of the transmission line 3 (the wiring impedance in the communication bus). The effect of ringing suppression operated by the suppressor 7 is further enhanced.

The operation controller 8 controls the operation of the suppressor 7. In particular, when the operation controller 8 detects that the signal level of a differential signal is changed to the signal level representing a recessive level, the operation controller 8 controls the suppressor 7 to start the suppression operation by turning on the switch 9 in the suppressor 7.

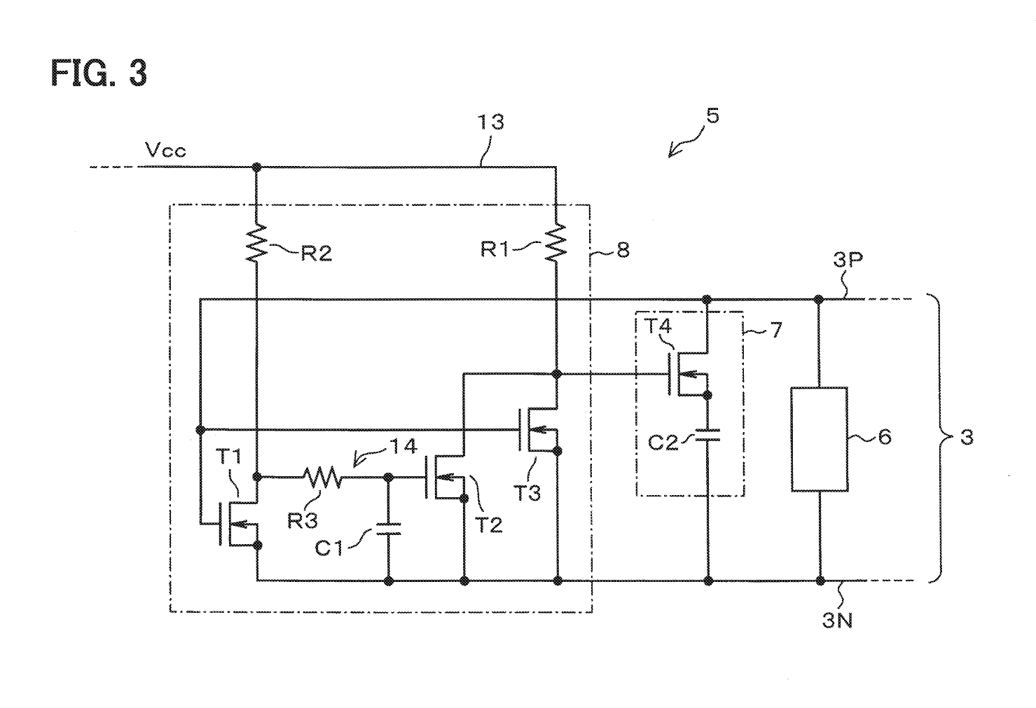

For a particular configuration of such a suppression circuit 5, a configuration as shown in FIG. 3 can be utilized as one of the examples. As illustrated in FIG. 3, the ringing suppression circuit 5 and the communication circuit 6 are connected in parallel between the signal lines 3P and 3N. The ringing suppression circuit 5 includes transistors T1 to T4 as n-channel MOSFETs.

The respective sources of the transistors T1 to T3 are connected to the signal line 3N. The respective gates of the transistors T1, T3 are connected to the signal line 3P. The respective drains of the transistors T2, T3 are connected to the gate of the transistor T4, and are connected to a power supply line 13 through a resistor RL The power supply line 13 is provided with a power supply Vcc (for example, 5V) for the operation of the ringing suppression circuit 5.

The drain of the transistor T1 is connected to the power supply line 13 through the resistor R2, and is connected to the gate of the transistor T2 through the resistor R3. The gate of the transistor T2 is connected to the signal line 3N through a capacitor C1. A resistor R3 and a capacitor C1 constitute an RC filter circuit 14.

The drain of the transistor T4 is connected to the signal line 3P, and the source of the transistor T4 is connected to the signal line 3N through a capacitor C2. That is, the transistor T4 and the capacitor C2 are connected in series between the signal lines 3P and 3N.

In such a configuration, the suppressor 7 includes the transistor T4 and the capacitor C2. In this case, the on-resistance of the transistor T4 functions as the resistive component 10, and the switching operation performed by the transistor T4 functions as the switch 9. The capacitor C2 corresponds to the capacitive component 11. The operation controller 8 is configured by the transistors T1 to T3, the resistors R1 to R3 and the capacitor C1.

The following describes an operation of the above configuration.

In this case, the transmission line 3 transmits a binary signal having a high level or a low level as a differential signal. For example, when the power supply is 5V, the signal lines 3P and 3N are set at 2.5V as a midpoint voltage at a non-driven state. The differential voltage is 0V, and thus the differential signal is at the low level representing the recessive level.

When the transmission circuit (not shown) in the communication circuit 6 drives the transmission line 3, the signal line 3P is driven at, for example, 3.5V or higher, and the signal line 3N is driven at, for example, 1.5V or lower, and thus the differential voltage is 2V or higher, and the differential signal is at the high level representing a dominant level. Although it is not shown, both ends of the signal lines 3P and 3N are terminated with a terminating resistor of 120 Ω. When the signal level of the differential signal is changed from the high level to the low level, the transmission line 3 is at the non-driven state and the impedance of the transmission line 3 gets larger. Thus, ringing occurs in the waveform of the differential signal.

The ringing suppression circuit 5 controls the suppressor 7 to start the suppression operation by turning on the transistor T4 when the signal level of the differential signal is changed from the high level to the low level representing the recessive level as a trigger circumstance. This operation is achieved as described in the following. When the level of the differential signal is at the high level, since the transistors T1, T3 are turned on, the transistor T2 is turned off. Accordingly, the transistor T4 is at an off state.

After the situation as described above, when the signal level of the differential signal is changed from the high level to the low level, since the transistors T1, T3 are turned off, the transistor T4 is turned on. As the signal lines 3P and 3N are connected through the on-resistance of the transistor T4 and the capacitor C2, the AC impedance between the signal lines 3P and 3N gets lower. Accordingly, the energy of the waveform distortion is consumed by the on-resistance, and thus the ringing is suppressed. The waveform distortion occurs at a falling edge of the differential signal. The falling edge of the differential signal refers to a situation where the signal level is changed from the high level to the low level.

According to the present embodiment described above, the following effects can be attained.

The effect attained in the present embodiment can be further clarified by comparing with the configuration without the ringing suppression circuit (hereinafter referred to as “First Comparative Example”) and the configuration provided with a conventional ringing suppression circuit used to connect only the resistive component between the signal lines 3P and 3N during the suppression operation (hereinafter referred to as “Second Comparative Example”).

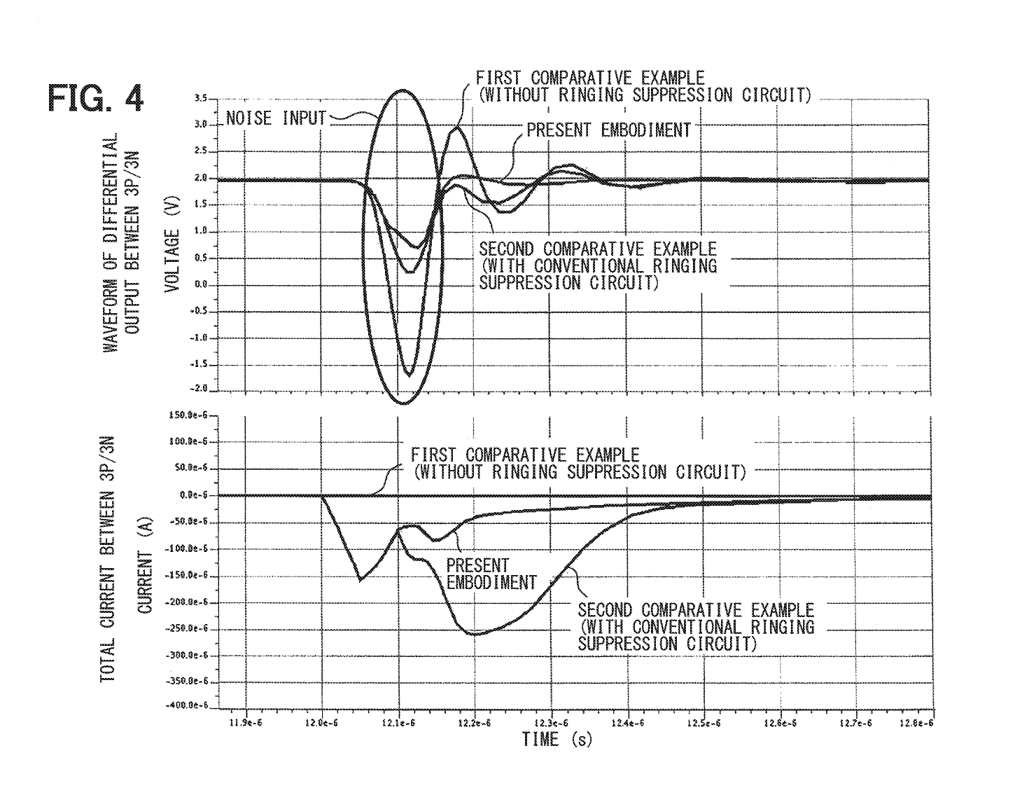

The following describes the comparison between the present embodiment and the comparative examples while describing the effects attained by the present embodiment with reference to FIG. 4, and illustrates the simulation results of the circuit operation in the respective comparative examples and the simulation result of the circuit operation in the present embodiment. It is noted that FIG. 4 illustrates the differential output waveform between the signal lines 3P and 3N and the total current waveform in a situation where noise is superimposed when the differential signal is at the signal level representing the dominant level for the comparative examples and the present embodiment.

### [1] FIRST COMPARATIVE EXAMPLE

In the first comparative example, since a ringing suppression circuit is not provided at the node 2, noise is superposed at the transmission line 3 and thus comparatively larger ringing occurs. Therefore, it takes a relatively longer time until the level of the differential signal returns to the level representing the dominant level to be stable. Accordingly, in the first comparative example, a fault such as the reception of erroneous data may occur. Since there is no configuration to connect the signal lines 3P and 3N, the total current is to be constant at the value of zero between the signal lines 3P and 3N.

### [2] SECOND COMPARATIVE EXAMPLE

In the second comparative example, when the noise is superimposed at the transmission line 3, as the suppression operation is performed by the ringing suppression circuit, the ringing is suppressed to be smaller as compared with the first comparative example. However, in this situation, the DC impedance instantaneously changes significantly between the signal lines 3P and 3N, and thus it is required to take a relatively longer time until the signal level of the differential signal returns to the signal level representing the dominant level to be stable. Accordingly, the second comparative example is similar to the first comparative example such that a fault may occur at the communication bus. In the second comparative example, since a current fluctuation is larger between the signal lines 3P and 3N, the influence on emission noise gets larger.

### [3] THE PRESENT EMBODIMENT

In the present embodiment, when noise is superimposed on the transmission line 3, the suppression operation of the ringing suppression circuit 5 is performed to suppress the ringing to a smaller level as compared with the first comparative example. Moreover, when the suppression operation of the ringing suppression circuit 5 is performed, the on-resistance of the transistor T4 as the resistive component 10 and the capacitor C2 as the capacitive component C2 are connected in series. Therefore, the DC impedance between the signal line 3P and the signal 3N does not change significantly.

The current fluctuation between the signal lines 3P and 3N is suppressed to a smaller scale as compared with the second comparative example. In the present embodiment, the signal level of the differential signal returns to the signal level representing the dominant level as an original signal level to be stable within a significantly shorter time as compared with the comparative examples as described above. According to the present embodiment, even when the suppressor 7 has an erroneous operation caused by the influence of noise, it is possible to attain the effect in preventing the occurrence of a fault. In the present embodiment, since the current fluctuation is smaller between the signal lines 3P and 3N, the influence on the emission noise can be significantly minimized.

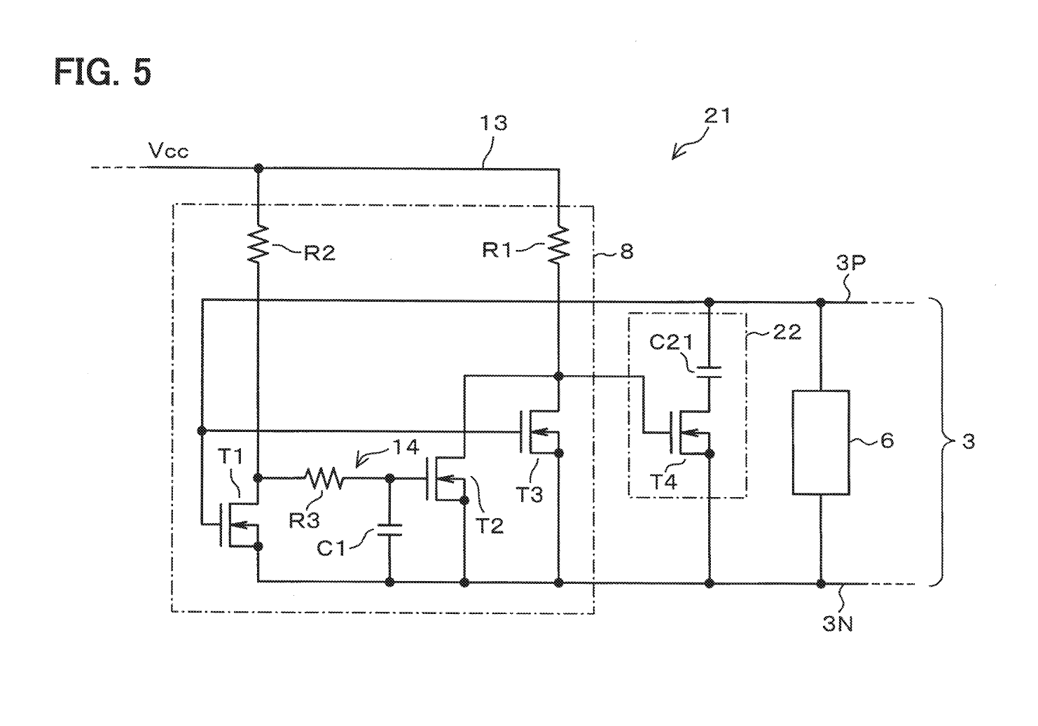

### SECOND EMBODIMENT The following describes a second embodiment with reference to FIGS. 5 to 7.

The present embodiment shows another example for configuring the suppressor.

A suppressor 22 of a ringing suppression circuit 21 illustrated in FIG. 5 is different from the suppressor 7 illustrated in FIG. 3 such that the suppressor 22 includes a capacitor C21, which is in replacement of the capacitor C2. In this case, the drain of the transistor T4 is connected to the signal line 3P through the capacitor C21, and the source of the transistor T4 is connected to the signal line 3N. In other words, the insertion position of the capacitive component 11 is modified in the suppressor 22 with respect to the suppressor 7.

Even with such a configuration, when the suppression operation is performed, the capacitor C2 as the capacitive component 11 and the on-resistance of the transistor T4 as the resistive component 10 are connected in series between the signal lines 3P and 3N. Therefore, the similar effect as in the first embodiment can also be attained.

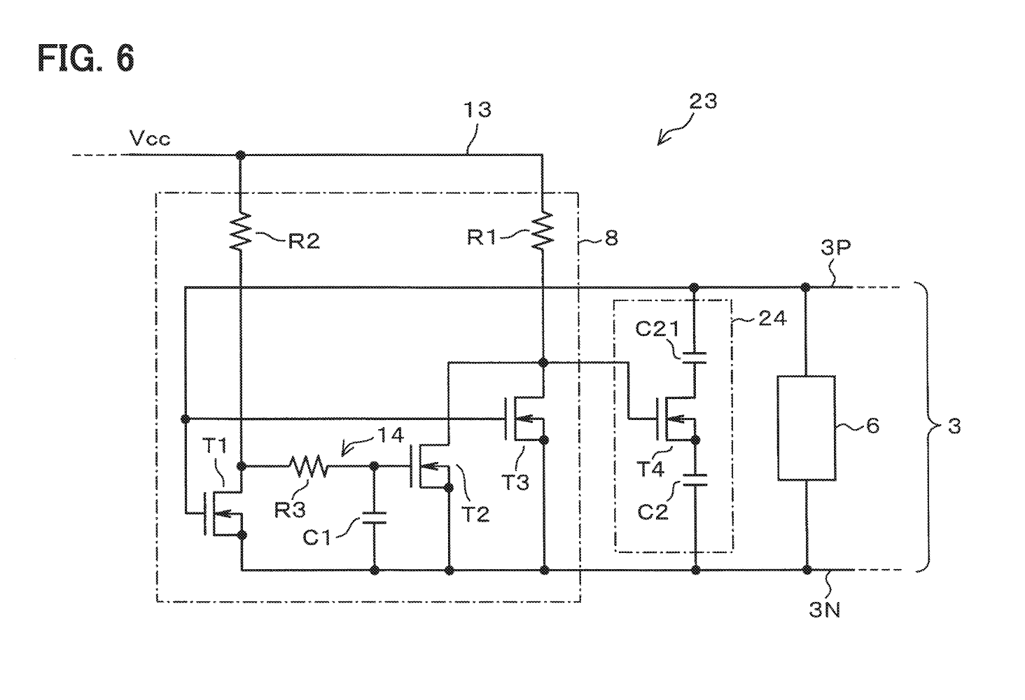

The suppressor 24 of the ringing suppression circuit 23 as illustrated in FIG. 6 is different from the suppressor 7 illustrated in FIG. 3 such that the capacitor C21 illustrated in FIG. 5 is added. The drain of the transistor T4 is connected to the signal line 3P through the capacitor 21, and the source of the transistor T4 is connected to the signal line 3N through a capacitor C2.

In such a configuration, the capacitor C21 corresponds to a first capacitor connected between the signal line 3P and the on-resistance of the transistor T4, and the capacitor C2 corresponds to a second capacitor connected between the on-resistance of the transistor T4 and the signal line 3N.

Even when the ringing suppression circuit 23 is configured as described above, when the suppression operation is performed, the capacitors C2, C21 as the capacitive component 11 and the on-resistance of the transistor T4 as the resistive component 10 are connected between the signal lines 3P and 3N. Therefore, the present embodiment can also attain the same effects as those of the first embodiment.

In this case, the capacitor C21 and the capacitor C2 both of which having the same capacitance values are opposite to each other with respect to the on-resistance of the transistor T4. In other words, a symmetrical configuration is formed. With regard to such a configuration, when the suppression operation is performed caused of the influence of noise, it is possible to further shorten the period during which the signal level of the differential signal returns to the original signal level. When the respective capacitance values of the capacitor C2 and the capacitor C21 are made to be equal, the effect can be further enhanced.

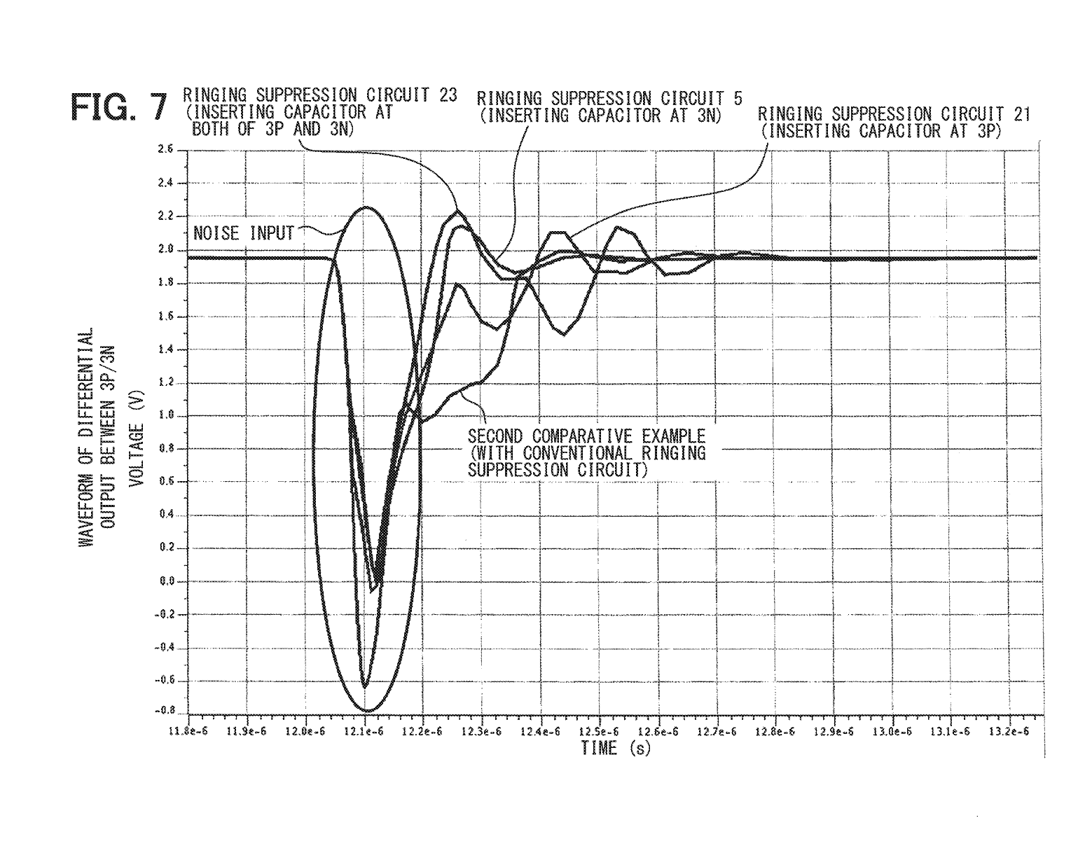

Such effect is apparent from FIG. 7 that illustrates the simulation results related to the respective circuit operations of the ringing suppression circuits 5, 21 and 23. FIG. 7 illustrates a differential output waveform between the signal lines 3P and 3N in a situation when noise is superimposed during the differential signal being at the dominant level. As illustrated in FIG. 7, with regard to any one of the ringing suppression circuits 5, 21 and 23, when noise is superimposed on the transmission line 3, the suppression operation is performed for ringing suppression.

Although the ringing suppression circuit 23 has the suppressor 24 provided with the capacitive components at both sides of the transistor T4, it also takes a shorter time for the signal level of the differential signal returning to the dominant level to be stable as compared with the ringing suppression circuits 5 and 21 respectively having the suppressors 7 and 22. The suppressor 7 is provided with the capacitive component above the transistor T4, The suppressor 22 is provided with the capacitive component below the transistor T4. According to the ringing suppression circuit 23, it is possible to attain the effect of further lowering the possibility in having a fault.

### THIRD EMBODIMENT

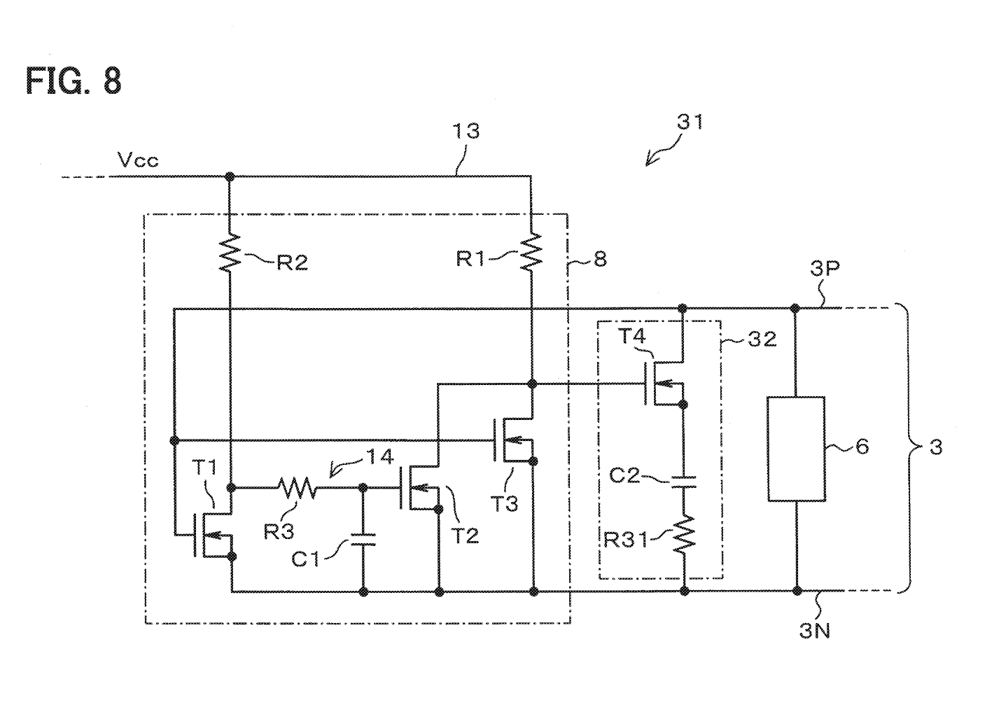

The following describes a third embodiment with reference to FIGS. 8 to 10.

The present embodiment shows another example for configuring the suppressor.

A suppressor 32 of a ringing suppression circuit 31 illustrated in FIG. 8 is different from the suppressor 7 illustrated in FIG. 8 such that the resistor R31 is added to the suppressor 32. In this case, the source of the transistor T4 is connected to the signal line 3N through the capacitor C2 and the resistor R31. In other words, the transistor T4, the capacitor C2 and the resistor R31 are connected in series between the signal lines 3P and 3N. It is noted that the respective connection positions of the capacitor C2 and the resistor R31 can be interchanged.

In the configuration as described above, the combined resistance formed by a series connection of the on-resistance of the transistor T4 and the resistor R31 functions as the resistive component 10. Even with the ringing suppression circuit 31 configured as described above, when the on-resistance of the transistor T4 and the resistor R31 as the resistive component 10 and the capacitor C2 as the capacitive component 11 are connected in series between the signal lines 3P and 3N. Therefore, the present embodiment can also attain the same effects as those of the first embodiment.

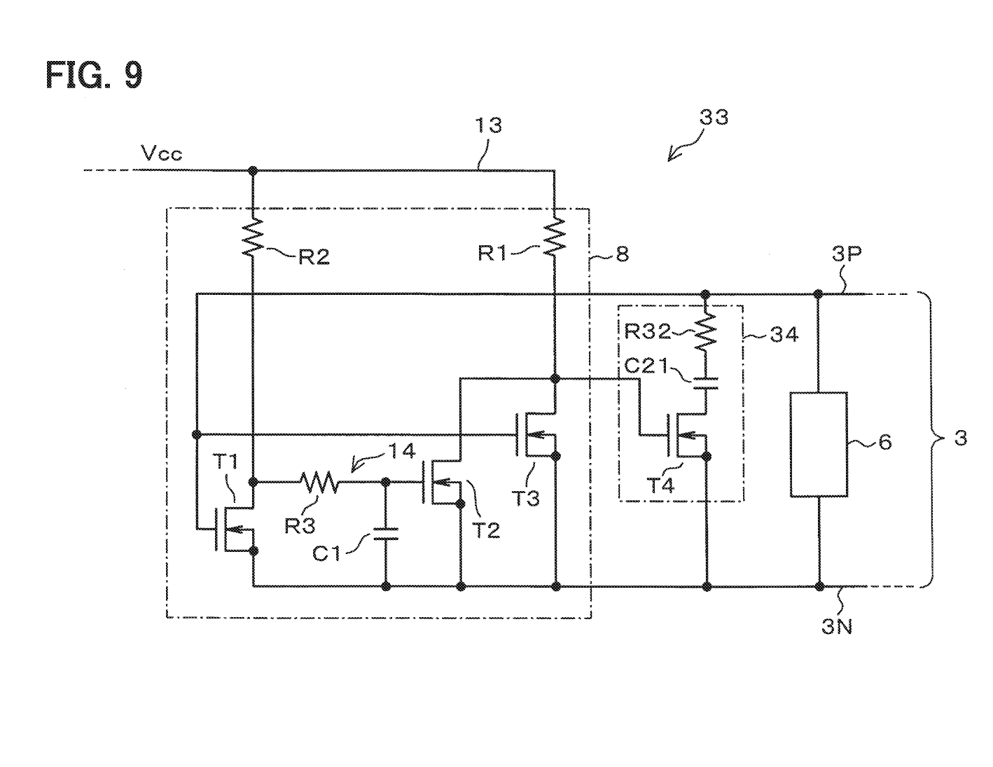

A suppressor 34 of a ringing suppression circuit 33 illustrated in FIG. 9 is different from the suppressor 22 illustrated in FIG. 5 such that a resistor R32 is added to the suppressor 34. In this case, the drain of the transistor T4 is connected to the signal line 3P through the capacitor C21 and the resistor R32. In other words, the resistor R32, the capacitor C21 and the transistor T4 are connected in series between the signal lines 3P and 3N. The respective connection positions of the capacitor C21 and the resistor R32 can be interchanged.

In the configuration as described above, the combined resistance formed by a series connection of the resistor R32 and the on-resistance of the transistor T4 functions as the resistive component 10. Even when the ringing suppression circuit 33 is configured as described above, when the suppression operation is performed, the resistor R32 and the on-resistance of the transistor T4 as the resistive component 10 and the capacitor C21 as the capacitive component 11 are connected in series. Therefore, the present embodiment can also attain the same effects as those of the first embodiment.

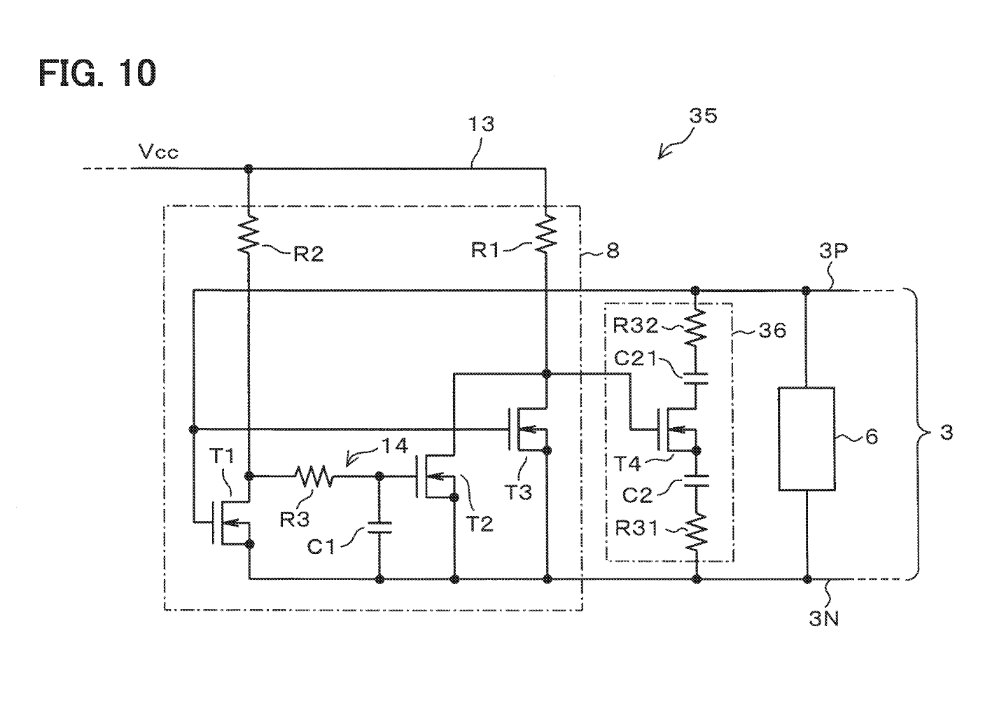

A suppressor 36 of a ringing suppression circuit 35 illustrated in FIG. 10 is different from the suppressor 24 illustrated in FIG. 6 such that resistors R31 and R32 are added to the suppressor 36. In this case, the drain of the transistor T4 is connected to the signal line 3P through the capacitor C21 and the resistor R32.

The source of the transistor T4 is connected to the signal 3N through the capacitor C2 and the resistor R31. In other words, the resistor R32, the capacitor C21, the transistor T4, the capacitor C2 and the resistor R31 are connected in series between the signal 3P and the signal 3N.

In the above-mentioned configuration, the combined resistance formed by the series connection of the resistor R32, the on-resistance of the transistor T4 and the resistor R31 functions as the resistive component 10. Even when the ringing suppression circuit 35 is configured as described above, when the suppression operation is performed, the resistor R32, the on-resistance of the transistor T4 and the resistor R31 as the resistive component 10 and the capacitors C21 and C2 as the capacitive component 11 are connected in series between the signal lines 3P and 3N. Therefore, the present embodiment can also attain the same effects as those of the first embodiment.

As described above, each of the above configurations in the present embodiment with the addition of the resistors R31 and R32 can attain the same effects as those of the first embodiment. Each configuration related to the present embodiment can attain the following effects. In other words, the on-resistance of the transistor T4 as a MOSFET varies widely. For this reason, when only the on-resistance of the transistor T4 is used as the resistive component 10, it is difficult to set the line impedance (hereinafter referred as “matching impedance”) in higher accuracy when the suppression operation is performed.

The resistors R31 and R32 are possible to minimize a fluctuation of resistance values as compared with the on-resistance of the MOS transistor. In each configuration related to the present embodiment, the respective resistance values of the resistor R31 and the resistor R32 may be set at a value larger than the value of the on-resistance of the transistor T4. With regard to the setting of the matching impedance, the influence on the on-resistance having large fluctuation can be suppressed to a minimum value, and thus the matching impedance can be set in higher accurately.

### OTHER EMBODIMENTS

The present disclosure is not limited to the embodiments that have been described above and illustrated in the drawings, but can arbitrarily be modified, combined, or expanded without departing from the gist of the present disclosure.

For the particular configuration of the suppressor, it may be properly modified as long as it performs an operation to suppress ringing caused by the transmission of a differential signal by lowering the AC impedance in the transmission line 3 when the level of the differential signal is changed. For example, the configuration described in JP 2012-244220 A, that is, the configuration in which a plurality of switching devices connected in series between the signal lines 3P and 3N, may also be utilized as the suppressor. The switching device may not be limited to an n-channel MOSFET. The switching device may also be a p-channel MOSFET. In addition, as illustrated in, for example, FIG. 6 of JP 2012-257205 A, the configuration in which the suppressor including the n-channel MOSFET and the suppressor including the p-channel MOSFET are connected in parallel at the transmission line 3 may also be utilized. When the suppressor including the p-channel MOSFET is utilized, the configuration of the operation controller 8 may also be modified to conform to the modification of the suppressor. In any configurations to be utilized, a capacitive component such as a capacitor may be inserted to be connected in series with a resistive component such as the on-resistance of a MOSFET.

The communication protocol is not limited to CAN. Any protocol is applicable as long as it transmits a differential signal through a pair of communication lines.

Although the disclosure has been described in accordance with the embodiments, it is understood that the present disclosure is not limited to the above embodiments or structures. Various changes and modification may be made in the present disclosure. In addition, various combinations and configurations, as well as other combinations and configurations that include only one element, more, or less, fall within the scope and spirit of the present disclosure.

1. A ringing suppression circuit provided at a node having a communication circuit executing communication with another node by transmitting a differential signal through a pair of communication lines, the ringing suppression circuit comprising:
a suppression circuit configured to perform a suppression operation to suppress ringing occurred with a transmission of the differential signal by connecting an adjustment circuit between the pair of communication lines, the adjustment circuit including a resistive component and a capacitive component connected in series.

2. The ringing suppression circuit according to claim 1,
wherein the resistive component includes on-resistance of a MOSFET.

3. The ringing suppression circuit according to claim 2,
wherein the resistive component further includes a resistor.

4. The ringing suppression circuit according to claim 3,
wherein a resistance value of the resistor is set to be larger than a value of the on-resistance of the MOSFET.

5. The ringing suppression circuit according to claim 1,
wherein the capacitive component includes a capacitor.

6. The ringing suppression circuit according to claim 2,
wherein:
the pair of communication lines are a high-potential communication line and a low-potential communication line; and
the capacitive component includes
a first capacitor connected between the high-potential communication line and the on-resistance of the MOSFET, and
a second capacitor connected between the low-potential communication line and the on-resistance of the MOSFET.

7. The ringing suppression circuit according to claim 1, wherein:
a resistance value of the resistive component is set at a value conforming to a characteristic impedance of a transmission line having the pair of communication lines.

8. A ringing suppression circuit provided at a node having a communication circuit executing communication with another node by transmitting a differential signal through a pair of communication lines, the ringing suppression circuit comprising:
a suppressor that includes an adjustment circuit having a resistive component and a capacitive component connected in series, and that is configured to connect the adjustment circuit with the pair of communication lines to suppress ringing occurred with a transmission of the differential signal.
